(19) United States
(12) Patent Application Publication
(10) Pub. No.: US 2012/0248628 A1
(43) Pub. Date: Oct. 4, 2012

(54) SEMICONDUCTOR DEVICE AND METHOD OF FABRICATING THE SAME

(75) Inventors: Jun TANAKA, Mie-ken (JP); Koichi Miyashita, Mie-ken (JP); Yoriyasu Ando, Mie-ken (JP); Akira Tanimoto, Mie-ken (JP); Yasuo Takemoto, Kanagawa-ken (JP)

(73) Assignee: KABUSHIKI KAISHA TOSHIBA, Tokyo (JP)

(21) Appl. No.: 13/233,321

(22) Filed: Sep. 15, 2011

(30) Foreign Application Priority Data
Mar. 31, 2011 (JP) 2011-080242

(51) Int. Cl. H01L 23/48; H01L 21/50

(52) U.S. Cl. 257/777; 438/118; 257/E23.01; 257/E21.499

(57) ABSTRACT

According to one embodiment, a semiconductor device includes a control element provided above a main surface of a substrate through a first adhesion layer, a second adhesion layer provided to cover the control element a first semiconductor chip provided on the second adhesion layer, a bottom surface area of the first semiconductor chip being larger than a top surface area of the control element, and at least one side of an outer edge of the control element projecting to an outside of an outer edge of the first semiconductor chip.

### CROSS REFERENCE TO RELATED APPLICATION

This application is based upon and claims the benefit of priority from prior Japanese Patent Application No. 2011-080242, filed on Mar. 31, 2011, the entire contents of which are incorporated herein by reference.

### FIELD

Embodiments of the invention relate to a semiconductor device and a method of fabricating the same.

### BACKGROUND

In recent years, various development efforts have been underway on a semiconductor device including multiple semiconductor chips, contained in a single package. For the purpose of reducing the size of the package, a structure in which the multiple semiconductor chips are stacked one on another with an adhesive interposed between each two neighboring semiconductor chips is used for the semiconductor device.

One method of fabricating the semiconductor device having the stacked structure is that a semiconductor chip having an adhesion layer on the lowermost surface is stacked on a control element which is smaller in size than the semiconductor chip.

In this case, the adhesion layer between the control element and the semiconductor chip deforms the semiconductor chip provided above the control element. For this reason, the deformation adversely affects the reliability of the operation of the semiconductor chip, and the reliability of the joint between the semiconductor chip and the adhesion layer. This has been pointed out as a problem.

### BRIEF DESCRIPTION OF THE DRAWINGS

FIG. 1 is a cross-sectional view showing a semiconductor device according to a first embodiment;

FIG. 2 is a plan view showing a semiconductor device according to the first embodiment;

FIG. 3 is a cross-sectional view showing a semiconductor device according to the first embodiment;

FIGS. 4A to 4E are cross-sectional views showing a method of fabricating a semiconductor device according to the first embodiment;

FIG. 5 is a cross-sectional view showing a semiconductor device according to a second embodiment;

FIG. 6 is a plan view showing a semiconductor device according to the second embodiment;

FIGS. 7A to 7D are cross-sectional views showing a method of fabricating a semiconductor device according to the second embodiment.

### DETAILED DESCRIPTION

According to one embodiment, a semiconductor device includes a control element provided above a main surface of a substrate through a first adhesion layer, a second adhesion layer provided to cover the control element a first semiconductor chip provided on the second adhesion layer, a bottom surface area of the first semiconductor chip being larger than a top surface area of the control element, and at least one side of an outer edge of the control element projecting to an outside of an outer edge of the first semiconductor chip.

### First Embodiment

Descriptions will be hereinbelow provided for the embodiments while referring to the drawings.

Through the descriptions for the following embodiments, the same portions shown throughout the drawings will be denoted by the same reference numerals, and detailed descriptions for such portions will be omitted whenever deemed possible. On the other hand, descriptions will be provided for different portions, depending on the necessity. In addition, words indicating directions, such as upper, lower, left and right, which are used to describe the embodiments, denote relative directions on the assumption that a surface on which the below-described solder balls 11 are provided is located lower than any other portions, except for the solder balls. For this reason, the relative direction may be different from the directions with respect to the direction of the acceleration of gravity.

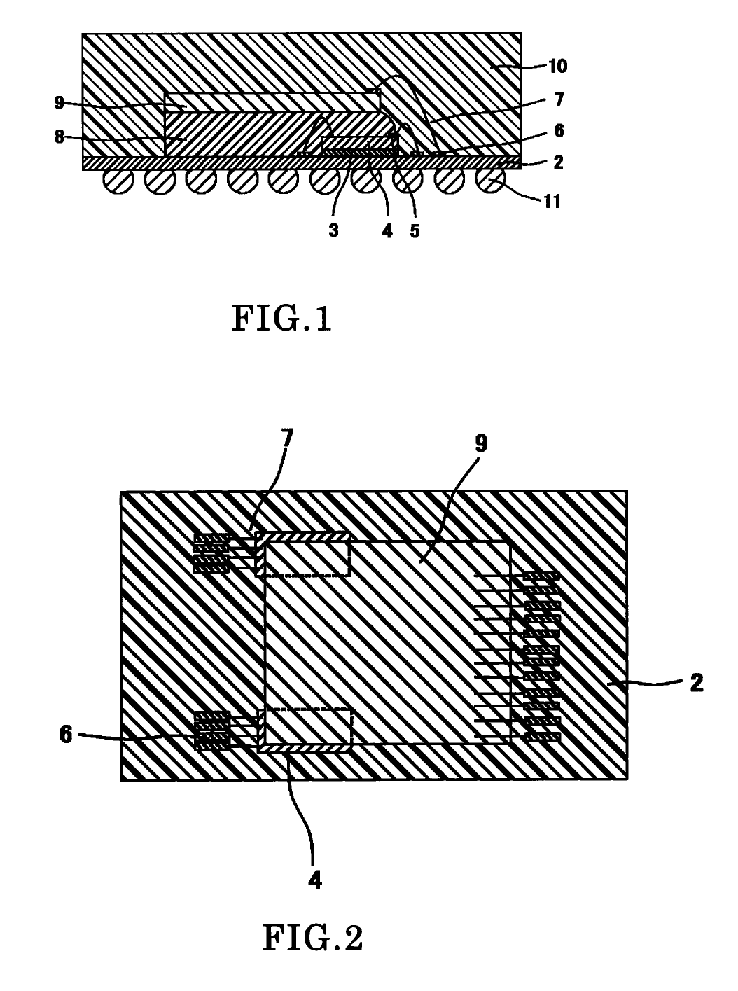

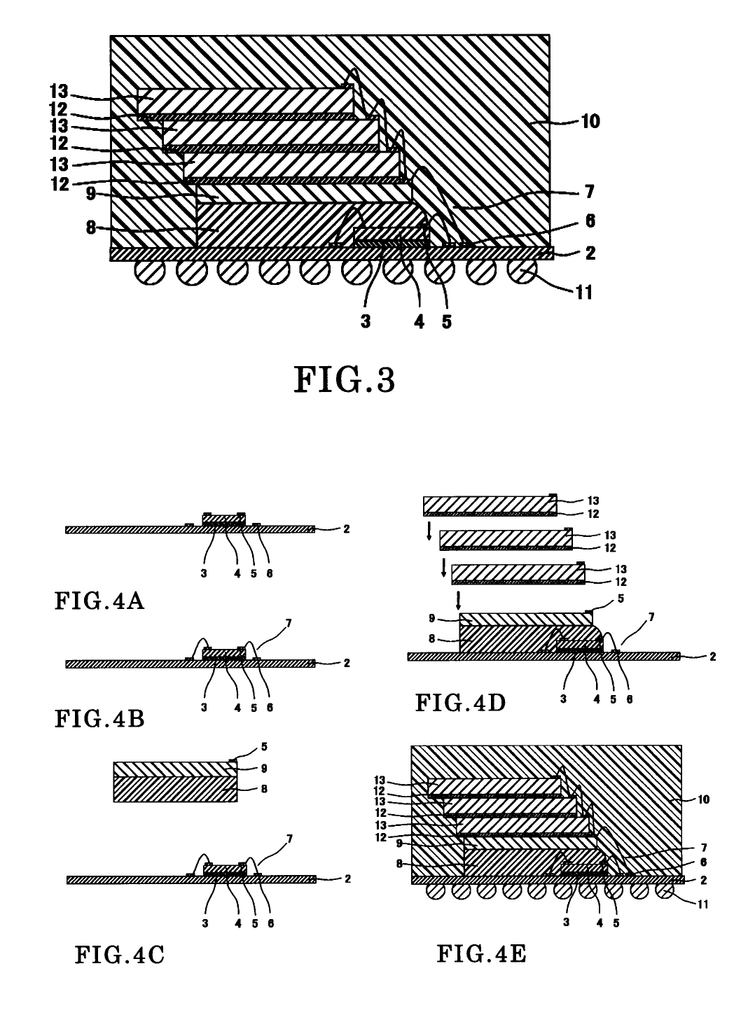

FIGS. 1 and 3 are cross-sectional views showing a semiconductor device 1 according to a first embodiment. FIG. 2 is a plan view showing the semiconductor device 1 according to the first embodiment. The semiconductor device 1 shown as an example is a semiconductor device contained in what is termed as a BGA (Ball Grid Array)-type semiconductor package.

A semiconductor chip 9 is a NAND flash memory, for example. Control elements 4 are memory controllers, for example, and control the operation of the semiconductor chip 9.

As shown in FIG. 1, the semiconductor device 1 includes a substrate 2, the control elements 4 provided above the substrate 2, and the semiconductor chip 9 provided above the control elements 4 with an adhesion layer 8 interposed between the semiconductor chip 9 and the control elements 4. A glass epoxy substrate including multi-layered interconnections, for example, is used as the substrate 2.

Each control element 4 is mounted on the top surface of the substrate 2 with an adhesion layer 3, which is provided on the back surface of the control element 4. Namely, the adhesion layer 3 is interposed between the control element and the substrate 2. A thermosetting epoxy resin, for example, is used for the adhesion layer 3. The adhesion layer 3 is approximately 10 μm, for example, in the film thickness, while the control element 4 is approximately 30 μm, for example, in the chip thickness. Electrode pads 5 are provided on each control element 4. The electrode pads 5 are electrically connected to connection terminals 6, which are provided on the top surface of the substrate 2, through metal wires 7, respectively.

The adhesion layer 8 is provided in a way that makes the adhesion layer 8 cover the control elements 4. The adhesion layer 8 may cover a portion of each control element 4, for example, a portion of the top surface of the control element 4, or portions of the top and side surfaces of the control element 4. Otherwise, the adhesion layer 8 may cover the entire top and side surfaces of each control element 4.

A portion of the adhesion layer 8 may be provided outside the outer edge of the semiconductor chip 9 in a way that the volume of the portion is equal to the sum of the volumes of portions of the adhesion layers 3 and the volumes of portions of the control elements 4, which are situated inside the outer edge of the semiconductor chip 9. In this case, a portion of the adhesion layer 8 which is situated inside the outer edge of the semiconductor chip 9 is discharged to the outside of the outer edge of the semiconductor chip 9. This leads to a decrease in the stress applied from the adhesion layer 8 to the semiconductor chip 9, and accordingly inhibits the deformation of the semiconductor chip 9.

As the adhesion layer 8, a DAF (Die Attach Film), for example, is attached to the back surface of the semiconductor chip 9, and the resultant DAF is compression-bonded to the control elements 4. The adhesion layer 8 contains an epoxy resin, for example. The viscosity of the adhesion layer 8 is 100 to 10000 Pa·S at a temperature in a range of 80 to 160° C., for example. The film thickness of the adhesion layer 8 is 40 to 150 μm, for example.

The semiconductor chip 9 is provided on the adhesion layer 8. The area of the bottom surface of the semiconductor chip 9 is larger than the sum of the areas of the top surfaces of the control elements 4. In addition, as shown in FIG. 2, at least one side of the outer edge of each control element 4 projects beyond the outer edge of the semiconductor chip 9 when viewed in the plan view. In a case where, as shown in FIG. 2, two sides of the outer edge of each control element 4 project beyond the outer edge of the semiconductor chip 9 when viewed in the plan view, a portion of the adhesion layer 8 is easily discharged to the outside of the outer edge of the semiconductor chip 9. This makes it possible to inhibit the deformation of the semiconductor chip 9.

Other electrode pads 5 provided on the semiconductor chip 9 are connected to the connection terminals 6 provided on the top surface of the substrate 2 by use of the respective metal wires 7.

Semiconductor chips 13 may be provided above the semiconductor chip 9 with an adhesion layer 12 interposed between each two neighboring semiconductors, as shown in FIG. 3. As shown in FIG. 3, the semiconductor chips 13 are stacked by shifting the positions of the semiconductor chips stepwise in the horizontal direction in way that the electrode pads 5 on the semiconductor chip 9 and the electrode pads 5 on each semiconductor chip 13 are exposed to the outside. The semiconductor chip 9 and the semiconductor chips 13 each are approximately 30 to 100 μm in the chip thickness. The connection terminals 6 on the substrate 2 are electrically connected to the solder balls 11 provided on the back surface of the substrate 2 through an interconnection layer (whose illustration is omitted) provided inside the substrate 2. The solder balls 11 are connected to an external circuit. Accordingly, the solder balls 11 electrically connect the semiconductor chip 9 and the control elements 4 to the external circuit.

In addition, an encapsulation resin 10 is provided in a way that makes the encapsulation resin 10 cover the semiconductor chip 9 and the control elements 4. Thereby, the semiconductor chip 9 and the control elements 4 are encapsulated in a way that the semiconductor chip 9 and the control elements 4 are not exposed to the outside.

The semiconductor device 1 of the first embodiment is provided with the foregoing configuration.

Next, descriptions will be hereinbelow provided for a method of fabricating the semiconductor device 1 of the first embodiment while referring to FIG. 4.

FIGS. 4A to 4E are cross-sectional views showing a method of fabricating the semiconductor device 1 according to the first embodiment.

First of all, as shown in FIG. 4A, control elements are stacked on a substrate 2 including multi-layered interconnections, which is made of a glass epoxy resin, with adhesion layers 3 interposed between the control elements 4 and the substrate 2. The adhesion layers 3 and the control elements 4 provided on the respective adhesion layers 3 are compression-bonded to the top surface of the substrate 2, for example. An epoxy resin, for example, with a thermosetting property is used for the adhesion layers 3. Thereafter, the adhesion layers 3 are caused to set by heating the substrate 2. Thereby, the control elements 4 are fixed to the top surface of the substrate 2.

As shown in FIG. 4B, metal wires 7 are provided to connect connection terminals 6 provided on the substrate to electrode pads 5 provided on the control elements.

As shown in FIG. 4C, the back surface of a semiconductor chip 9, on which an adhesion layer 8 is provided, is compression-bonded to the top surfaces of the control elements 4 and the face of the substrate 2 in a way that makes the back surface of the semiconductor chip 9 cover a portion of the top surface of each control element 4. On this occasion, the compression-bonding is carried out in a way that makes at least one side of the outer edge of each control element 4 project to the outside of the outer edge of the semiconductor chip 9. Thereby, a portion of the adhesion layer 8 is discharged to the outside of the outer edge of the semiconductor chip 9 in a way that the volume of the discharged portion is corresponded to the sum of the volumes of portions of the adhesion layers 3 and the volumes of portions of the control elements 4, which are situated inside the outer edge of the semiconductor chip 9 when viewed in the plan view. This reduces the stress applied from the adhesion layer 8 to the semiconductor chip 9, and accordingly inhibits the deformation of the semiconductor chip 9. The area of the bottom surface of the semiconductor chip 9 is larger than the sum of the areas of the top surfaces of the control elements 4.

The adhesion layer 8 is provided by attaching a DAF to the back surface of a semiconductor wafer on which the semiconductor chip 9 is provided, for example. Otherwise, the adhesion layer 8 may be provided by applying an adhesive, which contains a thermosetting resin, to the back surface of a semiconductor wafer, and subsequently by drying the adhesive.

A thermosetting epoxy resin, for example, with a low viscosity is used for the adhesion layer 8. The viscosity of the adhesion layer 8 should be 100 to 10000 Pa·S, for example, before the adhesion layer 8 is caused to set. The coefficient of elasticity of the adhesion layer 8 should be 1 to 1000 MPa, for example, after the adhesion layer 8 is caused to set. The use of the resin with the low viscosity for the adhesion layer 8 makes it possible to prevent the deformation of the metal wires 7. After that, the adhesion layer 8 is caused to set by heating the substrate 2. Thereby, the semiconductor chip 9 is fixed to the top surfaces of the control elements 4.

As shown in FIG. 4D, semiconductor chips 13, on whose back surfaces adhesion layers 12 are provided, are stacked above the semiconductor chip 9. The stacking is achieved by shifting the positions of the semiconductor chips 13 stepwise in the horizontal direction in a way that the electrode pads 5 on the semiconductor chip 9 and the electrode pads 5 on each semiconductor chip 13 are exposed to the outside.

The adhesion layers 12 provided on the back surfaces of the semiconductor chips 13 are caused to set by heating the substrate 2. Thereby, the semiconductor chips 13 stacked stepwise are fixed together, and to the semiconductor chip 9. Metal wires 7 are provided to connect the electrode pads 5 provided on the semiconductor chip 9 to the connection terminals 6, respectively.

As shown in FIG. 4E, an encapsulation resin 10 is provided on the substrate 2 in a way that makes the encapsulation resin 10 cover the control elements 4 and the semiconductor chip 9. Solder balls 11 are provided on the back surface of the substrate 2.

The semiconductor device 1 of the first embodiment shown in FIG. 1 is provided with the foregoing configuration.

In the first embodiment, at least one side of the outer edge of each control element 4 projects to the outside of the outer edge of the semiconductor chip 9 when viewed in the plan view. Accordingly, a portion of the adhesion layer is discharged to the outside of the outer edge of the semiconductor chip 9. This reduces the stress applied from the adhesion layer 8 to the semiconductor chip 9, and accordingly inhibits the deformation of the semiconductor chip 9.

Furthermore, in a case where two sides of the outer edge of each control element 4 projects to the outside of the outer edge of the semiconductor chip 9 when viewed in the plan view, a portion of the adhesion layer 8 is easily discharged to the outside of the outer edged of the semiconductor chip 9. Therefore, it is possible to further inhibit the deformation of the semiconductor chip 9.

### Second Embodiment

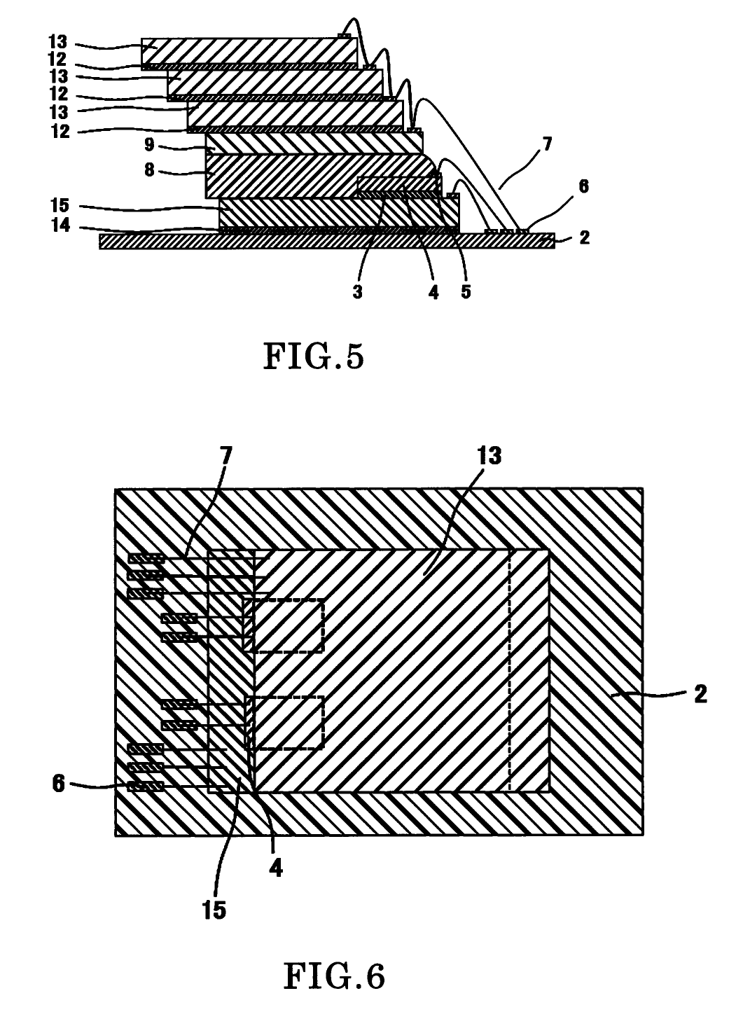

Descriptions will be provided for a semiconductor device 1 of a second embodiment by use of FIGS. 5 and 6. With regard to the configuration of the semiconductor device 1 of the second embodiment, portions which are the same as those included in the configuration of the semiconductor device 1 of the first embodiment shown in FIG. 1 are denoted by the same reference numerals, and detailed descriptions for such portions will be omitted.

What makes the second embodiment different from the first embodiment is that a semiconductor chip 15 is provided above a substrate 2 with an adhesion layer 14 interposed in between, and that control elements 4 are provided above the semiconductor chip 15 with an adhesive layer 3 interposed in between. Two control elements 4 may be provided above the semiconductor chip 15, as shown in FIG. 6.

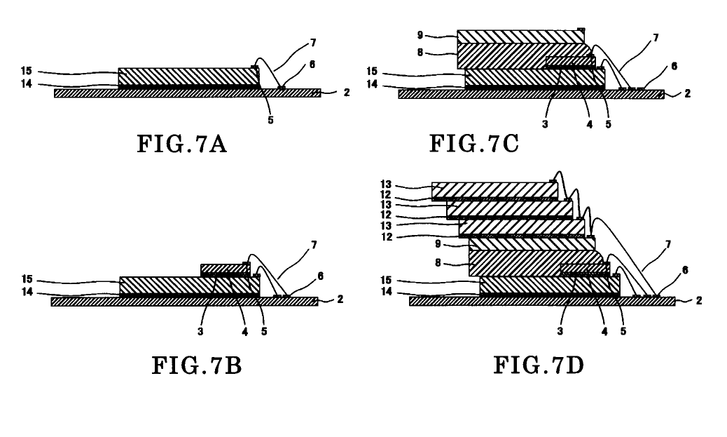

Descriptions will be provided for a method of fabricating the semiconductor device 1 according to the second embodiment while referring to FIG. 7.

As shown in FIG. 7A, the semiconductor chip 15 is stacked on a substrate 2 including multi-layered interconnections, which is made of a glass epoxy resin, with adhesion layers 14 interposed between the semiconductor chip 15 and the substrate 2. The adhesion layers 14 and the semiconductor chip 15 provided on the adhesion layers 14 are compression-bonded to the top surface of the substrate 2, for example. An epoxy resin, for example, with a thermosetting property is used for the adhesion layers 14. The adhesion layers 14 are caused to set by heating the substrate 2. Thereby, the semiconductor chip 15 is fixed to the top surface of the substrate 2. Metal wires 7 are used to connect connection terminals 6 provided on the substrate 2 to electrode pads 5 provided on the semiconductor chip 15.

As shown in FIG. 7B, the control elements 4 are stacked above the semiconductor chip 15 with adhesion layers 3 interposed in between, respectively. The adhesion layers 3 and control elements 4 provided on the respective adhesion layers 3 are compression-bonded to the top surface of the semiconductor chip 15, for example. An epoxy resin, for example, with a thermosetting property is used for the adhesion layers 3. The adhesion layers 3 are caused to set by heating the substrate 2. Thereby, the control elements are fixed to the top surface of the semiconductor chip 15. The connection terminals 6 provided on the substrate are connected with electrode pads 5 provided on each control element 4 by use of metal wires 7, respectively.

As shown in FIG. 7C, the back surface of a semiconductor chip 9, on which an adhesion layer 8 is provided, is compression-bonded to the top surfaces of the control elements 4 in a way that makes the back surface of the semiconductor chip 9 cover a portion of the top surface of each control element 4. On this occasion, the compression-bonding is carried out in a way that makes at least one side of the outer edge of each control element project to the outside of the outer edge of the semiconductor chip 9. The area of the bottom surface of the semiconductor chip 9 is larger than the sum of the areas of the top surfaces of the control elements 4.

A thermosetting epoxy resin, for example, with a low viscosity is used for the adhesion layer 8. The viscosity of the adhesion layer 8 should be 100 to 10000 Pa·S, for example, before the adhesion layer 8 is caused to set. The coefficient of elasticity of the adhesion layer 8 should be 1 to 1000 MPa, for example, after the adhesion layer 8 is caused to set. A portion of the adhesion layer 8 is discharged to the outside of the outer edge of the semiconductor chip 9 in a way that the volume of the discharged portion is corresponded to the sum of the volumes of portions of the adhesion layers 3 and the volumes of portions of the control elements 4, which are situated inside the outer edge of the semiconductor chip 9 when viewed in the plan view. This reduces the stress applied from the adhesion layer 8 to the semiconductor chip 9, and accordingly inhibits the deformation of the semiconductor chip 9. The adhesion layer 8 is caused to set by heating the substrate 2. Thereby, the semiconductor chip 9 is fixed to the top surfaces of the control elements 4.

As shown in FIG. 7D, semiconductor chips 13, on whose back surfaces adhesion layers 12 are provided, may be stacked above the semiconductor chip 9. The stacking is achieved by shifting the positions of the semiconductor chips 13 stepwise in the horizontal direction in a way that the electrode pads 5 on the semiconductor chip 9 and the electrode pads 5 on each semiconductor chip 13 are exposed to the outside.

The adhesion layers 12 provided on the back surfaces of the semiconductor chips 13 are caused to set by heating the substrate 2. Thereby, the semiconductor chips 13 stacked stepwise are fixed together, and to the semiconductor chip 9. Metal wires 7 are provided to connect the electrode pads 5 provided on the semiconductor chip 9 and the semiconductor chips 13 to the connection terminals 6, respectively.

As shown in FIG. 4E, an encapsulation resin 10 is provided on the substrate 2 in a way that makes the encapsulation resin 10 cover the control elements 4, the semiconductor chip 9 and the semiconductor chips 13, as in the case of the first embodiment. Solder balls 11 are provided on the back surface of the substrate 2.

The semiconductor device 1 of the second embodiment is provided with the foregoing configuration.

It should be noted that the metal wires 7 to connect the connection terminals 6 provided on the substrate 2, the control elements 4, and the electrode pads 5 provided on the semiconductor chip 9 may be provided at the same time after the semiconductor chip 15, the semiconductor chip 9 and the semiconductor chips 13 are stacked above the substrate 2.

Two or more semiconductor chips 15 may be provided, although the foregoing descriptions have been provided for the embodiment on the assumption that the single semiconductor chip 15 exists between the substrate 2 and the control elements 4.

As described above, in the second embodiment, at least one side of the outer edge of each control element 4 projects to the outside of the outer edge of the semiconductor chip 9 when viewed in the plan view. Accordingly, a portion of the adhesion layer 8 is discharged to the outside of the outer edge of the semiconductor chip 9. This reduces the stress applied from the adhesion layer 8 to the semiconductor chip 9, and accordingly inhibits the deformation of the semiconductor chip 9.

Furthermore, in a case where two sides of the outer edge of each control element 4 projects to the outside of the outer edge of the semiconductor chip 9 when viewed in the plan view, a portion of the adhesion layer 8 is easily discharged to the outside of the outer edged of the semiconductor chip 9. Therefore, it is possible to further inhibit the deformation of the semiconductor chip 9.

The semiconductor device 1 of the first embodiment and the semiconductor device 1 of the second embodiment have been described on the assumption that the multiple semiconductor chips 13 are stacked. Instead, however, the semiconductor device may be that in which only one semiconductor chip 13 is provided on the control elements 4.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a control element provided above a main surface of a substrate through a first adhesion layer;
a second adhesion layer provided to cover the control element;
a first semiconductor chip provided on the second adhesion layer, a bottom surface area of the first semiconductor chip being larger than a top surface area of the control element, and at least one side of an outer edge of the control element projecting to an outside of an outer edge of the first semiconductor chip.

2. The semiconductor device of claim 1, wherein
at least a portion of the second adhesion layer is provided outside of the outer edge of the first semiconductor chip, the portion of the second adhesion layer being corresponded to sum of volumes of a portion of the first adhesion layer and the control element which are situated inside an outer edge of the first semiconductor chip.

3. The semiconductor device of claim 1, wherein
two sides of the outer edge of the control element project to the outer edge of the first semiconductor chip.

4. The semiconductor device of claim 1, further comprising:
a second semiconductor chip provided between the substrate and the control element.

5. The semiconductor device of claim 1, further comprising:
a connection terminal provided on the substrate,
an electrode pad provided on the first semiconductor chip; and
a metal wiring connected between the connection terminal and the electrode pad.

6. The semiconductor device of claim 1, further comprising:
a plurality of the second adhesive layers and a plurality of the first semiconductor chips, each of the second adhesive layers being alternately stacked on the each of the first semiconductor chips.

7. The semiconductor device of claim 6, wherein
a position of the second adhesive layer is shifted to a bottom of the first semiconductor chip on the second adhesive layer in the horizontal direction.

8. The semiconductor device of claim 7, wherein
the electrode pad is provided on a portion of the first semiconductor chip other than a portion which is in contact with a bottom surface of the second adhesive layer.

9. The semiconductor device of claim 1, wherein
elastic modulus of the second adhesion layer 8 is ranged from 1 to 1000 MPa.

10. The semiconductor device of claim 1, wherein
a bottom surface area of the first semiconductor chip is larger than a top surface are of the control element.

11. A method of fabricating a semiconductor device, comprising:
compression-bonding a back surface of a control element on which a first adhesive layer is provided, onto a substrate; and
compression-bonding a back surface of a semiconductor chip on which a second adhesive layer is provided, onto a top surface of the control element and a top surface of the substrate; wherein
a bottom surface area of the semiconductor chip being larger than an upper surface area of the control element, and at least one side of an outer edge of the control element projects to an outside of an outer edge of the semiconductor chip in the compression-bonding the back surface of the semiconductor chip.

12. The method of claim 11, wherein
at least a portion of the second adhesion layer being corresponded to sum of volumes of a portion of the first adhesion layer and a portion of the control element which are situated inside an outer edge of the semiconductor chip, is provided outside of the outer edge of the semiconductor chip in the compression-bonding.

13. The method of claim 11, wherein
two sides of the outer edge of the control element project to the outer edge of the semiconductor chip in the compression-bonding.

14. The semiconductor device of claim 11, further comprising:
providing a plurality of the second adhesive layers and a plurality of the semiconductor chips alternately, each of the second adhesive layers on the each of the semiconductor chips.

15. The method of claim 14, wherein
a position of each second adhesive layer is shifted to a bottom of the semiconductor chip on the second adhesive layer in the horizontal direction.

16. A method of fabricating a semiconductor device, comprising:
providing a first semiconductor chip above a substrate;
compression-bonding a back surface of a control element on which a first adhesive layer is provided, onto a top surface of the first semiconductor chip; and
compression-bonding a back surface of a second semiconductor chip on which a second adhesive layer is provided, onto a top surface of the control element and the top surface of first semiconductor chip;
wherein a bottom surface area of the second semiconductor chip being larger than a top surface area of the control element, and at least one side of an outer edge of the control element projects to an outside of an outer edge of the second semiconductor chip in the compression-bonding the second semiconductor chip.

17. The method of claim 16, wherein
at least a portion of the second adhesion layer being corresponded to sum of volumes of a portion of the first adhesion layer and a portion of the control element which are situated inside an outer edge of the first semiconductor chip, is provided outside of the outer edge of the first semiconductor chip in the compression-bonding the second semiconductor chip.

18. The method of claim 16, wherein
two sides of the outer edge of the control element project to the outer edge of the first semiconductor chip in the compression-bonding the second semiconductor chip.

19. The semiconductor device of claim 16, further comprising:
providing a plurality of the second adhesive layers and a plurality of the first semiconductor chips alternately, each of the second adhesive layers on the each of the first semiconductor chips.

20. The method of claim 19, wherein
a position of each second adhesive layer is shifted to a bottom of the first semiconductor chip on the second adhesive layer in the horizontal direction.
